(19) United States
(12) Patent Application Publication
(10) Pub. No.: US 2025/0311127 A1
(43) Pub. Date: Oct. 2, 2025

(54) OPTICAL MODULE AND OPTICAL TRANSCEIVER CONNECTION ASSEMBLY

(71) Applicant: O-Net Technologies (Shenzhen) Group Co., Ltd., Shenzhen (CN)

(72) Inventors: Hailin Lv, Shenzhen (CN); Zhaofeng Zeng, Shenzhen (CN); Zining Huang, Shenzhen (CN); Baofeng Si, Shenzhen (CN)

(21) Appl. No.: 19/237,352

(22) Filed: Jun. 13, 2025

Related U.S. Application Data
(63) Continuation-in-part of application No. PCT/CN2022/143886, filed on Dec. 30, 2022.

(30) Foreign Application Priority Data
Apr. 29, 2025 (CN) 202520864995.X

(51) Int. Cl. H05K 5/02

(52) U.S. Cl. CPC H05K 5/0221

(57) ABSTRACT

This application relates to the technical field of optical communication, and in particular to an optical module and an optical transceiver connection assembly. The optical module includes a shell and mounting portions arranged at two opposite sides of the shell. The mounting portions are each provided with a reinforcing member. An unlocking member is further slidably connected in the shell. The shell is pluggable into a cage and clamped with locking tongues of the cage through the reinforcing members. The unlocking member is capable of undoing the clamping of the locking tongues to the reinforcing members. In this way, abrasion at locking positions can be reduced, thereby improving the connection stability.

### CROSS REFERENCE TO RELATED APPLICATIONS

The present application is a Continuation-In-Part Application of PCT Application No. PCT/CN2022/143886 filed on Dec. 30, 2022. The present application also claims the benefit of Chinese Patent Application No. 202520864995.X filed on Apr. 29, 2025. All the above are hereby incorporated by reference in their entirety.

### FIELD OF TECHNOLOGY

This application relates to the technical field of optical communication, and in particular to an optical module and an optical transceiver connection assembly.

### BACKGROUND

A pluggable optical module generally needs a shell-withdrawing unlocking structure, so that the optical module can be locked and prevented from coming out when being plugged into the device cage for use so as to avoid interruption of transmission signals, and can also be easily pulled out of the device cage when it needs to be taken out.

The fit between the optical module and the device cage is realized mainly through locking portions and elastic pieces. That is, the optical module is designed with locking portions in a fixed shape, and the device cage is designed with elastic pieces in a corresponding opening shape. When the device cage needs to be withdrawn from the optical module, the movable unlocking structure designed on the optical module can push up the elastic pieces in the device cage to unfasten the optical module from the device cage.

At present, the shell of the optical module is typically made by die casting, and the material is also limited to zinc alloy and die-casting aluminum alloy. The die-cast shell is subjected to nickel electroplating to form a protective layer. While the optical module is plugged into the device cage to be locked and unlocked, the elastic piece may scrape against the locking portion to varying degrees. The scraping will lead to peeling and scratches of the electroplated coating at the locking portion of the optical module. If a zinc alloy shell is used, the position where the electroplated coating peels will be pulverized after long-term use, which will affect the connection stability.

### SUMMARY

This application provides an optical module and an optical transceiver connection assembly, which can reduce abrasion at the locking positions and improve the connection stability.

This application discloses an optical module, including a shell and mounting portions arranged at two opposite sides of the shell. The mounting portions are each provided with a reinforcing member. An unlocking member is further slidably connected in the shell. The shell is pluggable into a cage and clamped with locking tongues of the cage through the reinforcing members. The unlocking member is capable of undoing the clamping of the locking tongues to the reinforcing members.

Optionally, the shell includes a bottom case and a top cover that are fastened with each other. The mounting portions are located at two opposite sides of the bottom case, and the unlocking member is slidably connected with the bottom case.

Optionally, the reinforcing member has a U-shaped structure. Support arms of the reinforcing member are respectively provided with a positioning protrusion, and the bottom case and the top cover are respectively provided with positioning grooves such that the positioning protrusions snap into the positioning grooves.

Optionally, the unlocking member includes a handle and connecting arms connected with the handle. The connecting arms are each provided with an unlocking clamping protrusion, and the unlocking clamping protrusion is configured to abut against the locking tongue.

Optionally, the unlocking clamping protrusion includes an extending portion and a bending portion that are connected with each other. The extending portion is connected with the connecting arm, and there is a preset included angle between the extending portion and the connecting arm. The bending portion bends toward an inner side of the unlocking member.

Optionally, the bottom case includes first baffles and second baffles that are spaced apart, and a sliding groove is formed between the first baffle and the second baffle such that the connecting arm slides along the sliding groove.

Optionally, the connecting arm is provided with a hook, the first baffle is formed with a clamping groove, and the hook is located in the clamping groove.

Optionally, the reinforcing members are made of stainless steel, tool steel or die steel.

Optionally, the unlocking member is provided with abutting blocks, and the abutting blocks are capable of abutting against the locking tongues such that the unlocking member undoes the clamping and limiting of the locking tongues to the reinforcing members through the abutting blocks.

Optionally, the unlocking member includes a handle and connecting arms connected with the handle. A tail end of each of the connecting arms is provided with a limiting portion, and the limit portion is in a snap-fit with the abutting block.

Optionally, the two opposite sides of the bottom case are further provided with sliding slots for limiting the abutting blocks, and part of the reinforcing member extends to the sliding slot to form a sliding fit with the abutting block.

Optionally, the abutting block includes a base connected with the limiting portion and a plurality of ribs formed at one side of the base. The ribs are each formed with a guide slope to be fitted with an end portion of the locking tongue. Guide grooves are formed between the adjacent ribs. The reinforcing member is formed with guide bumps corresponding to the ribs. The guide slots are slidable along the guide bumps.

Optionally, the limiting portion is T-shaped or L-shaped, and the base is provided with an insertion groove and a snap-fit groove located at at least one side of the insertion groove such that the limiting portion snaps into the snap-fit groove.

Optionally, the connecting arm is provided with a hook. Side walls of the bottom case are each formed with a clamping groove. The hook extends into the clamping groove. An elastic member is arranged in the clamping groove. Two ends of the elastic member respectively abut against the hook and one side wall of the clamping groove such that the connecting arm is subjected to an elastic force of sliding into the shell.

Optionally, a side of each of the connecting arms in a width direction is formed with a limiting protrusion. The top cover is formed with limiting grooves corresponding to the limiting protrusions. The limiting protrusion is slidably clamped in the limiting groove.

Optionally, the abutting blocks are made of stainless steel, tool steel or die steel.

This application further discloses an optical transceiver connection assembly, including a cage and the optical module according to any of the above. The optical module is pluggably connected with the cage. The cage includes an enclosure and locking tongues arranged at two opposite sides of the enclosure, and the locking tongues bend toward an inner side of the enclosure so as to be clamped with reinforcing members of the optical module.

Compared with the prior art, the optical module and the optical transceiver connection assembly provided by the embodiments of this application have the following beneficial effects: By arranging the reinforcing members on the mounting portions at the two opposite sides of the shell, the strength of positions where the optical module and the cage are connected is significantly improved. Unlike the shell of the optical module in the prior art in which the electroplated coating on the locking portions is prone to peeling and scratches due to the scraping of the elastic pieces, the reinforcing members can better bear the interaction force with the locking tongues during the plugging and unlocking process, which avoids forming pits on the reinforcing members due to the scraping of the locking tongues and avoids unlocking failure caused by the easily deformable thin metal sheets and edges of the elastic pieces hooked to the pits, thereby improving the reliability and stability of the unlocking operation of the optical module. In addition, compared with the unlocking structure in the prior art in which the protruding position presses against the elastic piece, the abutting block abutting against the locking tongue can prevent deformation failure itself from affecting the abutting against the locking tongue. Through the fit between the reinforcing member and the abutting block, the optical module can be plugged in and pulled out more smoothly, and the reliability during unlocking can be improved.

### BRIEF DESCRIPTION OF THE DRAWINGS

The technical solutions of this application will be further described in detail below in conjunction with the accompanying drawings and embodiments. In the accompanying drawings:

FIG. 1 is a schematic structural view I of an optical module according to an embodiment of this application;

FIG. 2 is a schematic structural view of a cage according to an embodiment of this application;

FIG. 3 is a schematic structural view II of the optical module according to an embodiment of this application;

FIG. 4 is a schematic structural view of a reinforcing member according to an embodiment of this application;

FIG. 5 is a schematic structural view of an unlocking member according to an embodiment of this application;

FIG. 6 is a partial enlarged view of A in FIG. 5;

FIG. 7 is a schematic structural view of a bottom case according to an embodiment of this application;

FIG. 8 is a partial enlarged view of B in FIG. 5;

FIG. 9 is a schematic structural view of an optical transceiver connection assembly according to an embodiment of this application;

FIG. 10 is a schematic structural view of the optical module according to another embodiment of this application;

FIG. 11 is a schematic partial enlarged view of Al in FIG. 10;

FIG. 12 is a schematic structural view of the cage according to another embodiment of this application;

FIG. 13 is a schematic exploded view of the optical module according to another embodiment of this application;

FIG. 14 is a schematic structural view I of an abutting block according to another embodiment of this application;

FIG. 15 is a schematic structural view II of the abutting block according to another embodiment of this application;

FIG. 16 is a schematic structural view of a reinforcing member according to another embodiment of this application;

FIG. 17 is a schematic structural view of a top cover according to another embodiment of this application;

FIG. 18 is a schematic structural view of the optical transceiver connection assembly in a locked state according to another embodiment of this application;

FIG. 19 is a schematic partial enlarged view of B1 in FIG. 18;

FIG. 20 is a schematic structural view of the optical transceiver connection assembly in an unlocked state according to another embodiment of this application; and

FIG. 21 is a schematic partial enlarged view of C1 in FIG. 20.

### REFERENCE SIGNS IN THE FIGURES

100, optical module; 110, shell; 112, mounting portion; 114, bottom case; 1141, first baffle; 1142, sliding slot; 1143, second baffle; 1144, clamping groove; 1146, elastic member; 116, top cover; 1162, limiting groove; 120, reinforcing member; 122, support arm; 124, positioning protrusion; 126, guide bump; 130, unlocking member; 131, abutting block; 1312, base; 1312a, insertion groove; 1312b, snap-fit groove; 1314, rib; 1314a, guide slope; 1316, guide groove; 132, handle; 134, connecting arm; 1342, limiting portion; 1344, limiting protrusion; 136, unlocking clamping protrusion; 1362, extending portion; 1364, bending portion; 138, hook; 200, optical transceiver connection assembly; 210, cage; 211, enclosure; 212, locking tongue.

### DESCRIPTION OF THE EMBODIMENTS

It should be noted that the embodiments in this application and the features in the embodiments may be combined with each other in the case of no conflict. Preferred embodiments of this application will be described in detail below with reference to the accompanying drawings.

At present, the shell of the optical module is typically made by die casting, and the die-cast shell is subjected to nickel electroplating. While the optical module is plugged into the device cage to be locked and unlocked, the elastic piece may scrape against the locking portion to varying degrees. The scraping will lead to peeling and scratches of the electroplated coating at the locking portion of the optical module. If a zinc alloy shell is used, the position where the electroplated coating peels will be pulverized after long-term use, which will affect the connection stability. The embodiments of this application provide the following technical solutions to solve the above problems.

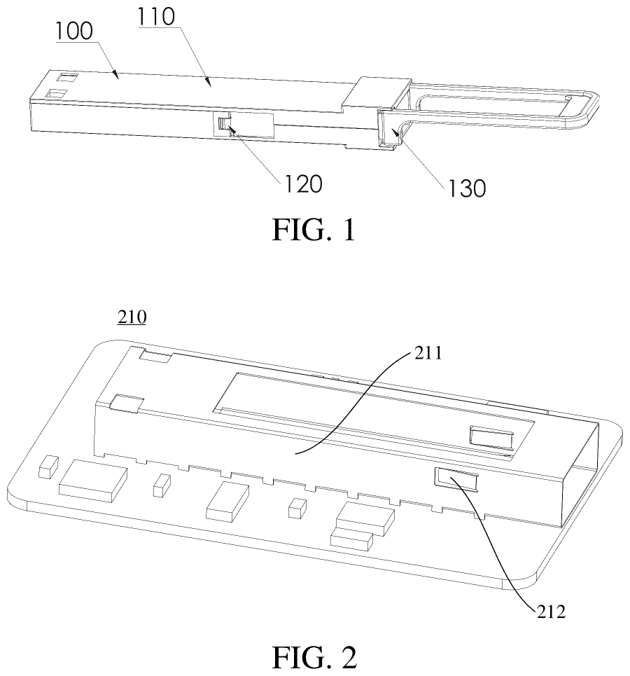

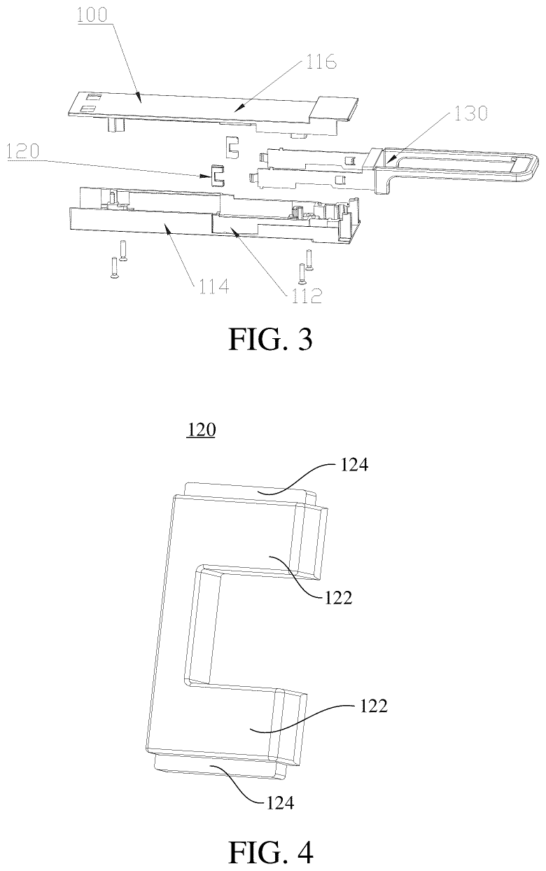

Referring to FIG. 1, FIG. 2, FIG. 3, FIG. 10 and FIG. 12, this embodiment provides an optical module 100, including a shell 110 and mounting portions 112 arranged at two opposite sides of the shell 110. The mounting portions 112 are each provided with a reinforcing member 120. An unlocking member 130 is further slidably connected in the shell 110. The shell 110 is pluggable into a cage 210 and clamped with locking tongues 212 of the cage 210 through the reinforcing members 120. The unlocking member 130 is capable of undoing the clamping of the locking tongues 212 to the reinforcing members 120.

Specifically, the shell 110 is usually strip-shaped, and the unlocking member 130 is slidable in the shell 110 along a length direction of the shell 110 to realize an unlocking function of the optical module 100. The shell 110 of the optical module 100 is pluggable into the cage 210, and after the shell is plugged in place, the reinforcing members 120 are clamped with the locking tongues of the cage 210. Through the clamping, the optical module 100 can be firmly fixed in the cage 210 without coming out, thereby avoiding interruption of transmission signals caused by loosening of the optical module 100 during the operating process. By arranging the mounting portions 112 at the two opposite sides of the shell 110, the reinforcing members 120 can be installed at the mounting portions 112, so that when the optical module 100 is clamped and fixed with the cage 210, the locking tongues 212 of the cage 210 can be clamped at the reinforcing members 120, thereby ensuring the stability of the relative position relationship between the optical module 100 and the cage 210. When the optical module 100 needs to be removed from the cage 210, it is only required to elastically deform the locking tongues 212 through the unlocking member 130 to avoid clamping with the reinforcing members 120 such that the optical module 100 can be removed from the cage 210. In addition, by arranging the reinforcing members 120 at the positions clamped with the locking tongues 212, the abrasion caused by the scraping of the locking tongues 212 can be avoided, thereby ensuring the stability in use.

According to the optical module 100 provided by this embodiment of this application, through the shell 110 and the mounting portions 112 arranged at the two opposite sides of the shell 110, since the mounting portions 112 are preserved mounting positions on the shell 110, the reinforcing members 120 can be mounted at the mounting positions, so that when the optical module 100 is fitted with the cage 210, the abrasion at the clamping and limiting positions caused by the locking and unlocking between the optical module 100 and the cage 210 can be avoided through the fit between the reinforcing members 120 and the locking tongues 212 at the positions easily scraped by the locking tongues 212. When the optical module 100 needs to be removed from the cage 210, it is only required for the unlocking member 130 to undo the clamping of the locking tongues 212 to the reinforcing members 120. In this way, the abrasion at the locking positions can be reduced, thereby improving the connection stability.

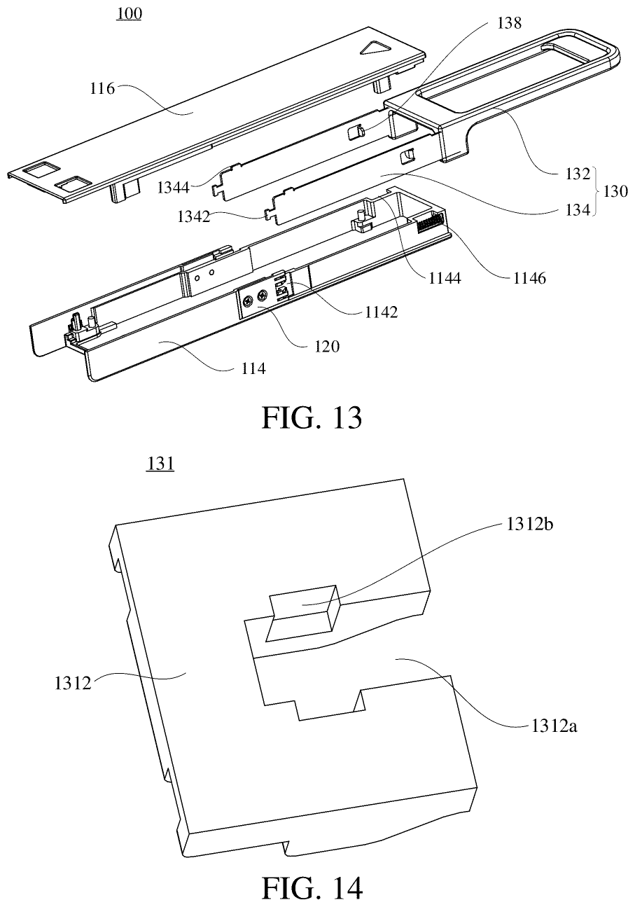

As shown in FIG. 3 and FIG. 13, the shell 110 includes a bottom case 114 and a top cover 116 that are fastened with each other. The mounting portions 112 are located at two opposite sides of the bottom case 114, and the unlocking member 130 is slidably connected with the bottom case 114.

Specifically, the bottom case 114 is fitted with the top cover 116 at the shell 110, which facilitates the mounting of the other components in the shell 110 and the mounting of the reinforcing members 120. During production, components such as electronic elements and optical elements may be mounted on the bottom case 114 first, and then the top cover 116 is fixed with the bottom case, which improves the production efficiency. During maintenance and repair, the top cover 116 can be opened easily, so that the components inside can be examined and replaced, which lowers the maintenance cost and difficulty. In addition, the unlocking member 130 is slidably connected with the bottom case 114, so that the position of the unlocking member 130 relative to the locking tongues 212 can be changed, thereby, the unlocking member 130 controls the locking tongues 212 to realize or undo the clamping of the locking tongues 212 to the reinforcing members 120. Moreover, the shaking and deviation of the unlocking member 130 during sliding can be reduced, thereby improving the accuracy and reliability of the unlocking operation.

As shown in FIG. 3 and FIG. 4, in an optional embodiment of this application, the reinforcing member 120 has a U-shaped structure. Support arms 122 of the reinforcing member 120 are respectively provided with a positioning protrusion 124, and the bottom case 114 and the top cover 116 are respectively provided with positioning grooves such that the positioning protrusions 124 snap into the positioning grooves.

Specifically, by arranging the reinforcing member 120 having the U-shaped structure, it is convenient to give way to the unlocking member 130, so that the unlocking member 130 can be better fitted with the locking tongues 212. In addition, by arranging the positioning protrusions 124 respectively on the support arms 122 of the reinforcing member 120, when the reinforcing members 120 are mounted to the mounting portions 112, the positioning protrusions 124 can respectively snap into the positioning grooves of the bottom case 114 and the top cover 116 so as to limit the reinforcing members 120, which prevents the reinforcing members 120 from moving relative to the shell 110 and helps in ensuring the connection reliability.

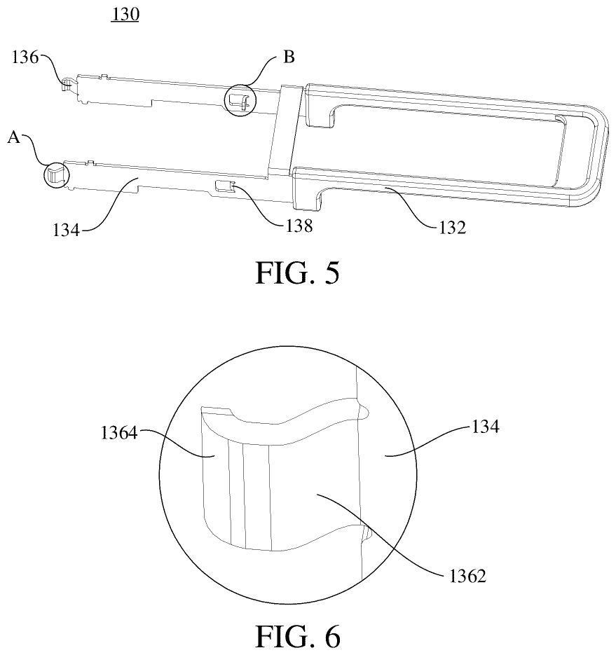

As shown in FIG. 5, the unlocking member 130 includes a handle 132 and connecting arms 134 connected with the handle 132. The connecting arms 134 are each provided with an unlocking clamping protrusion 136, and the unlocking clamping protrusion 136 is configured to abut against the locking tongue 212.

Specifically, with the handle 132, it is convenient to exert force to the unlocking member 130 such that the unlocking member 130 can slide relative to the shell 110. When the unlocking member 130 slides toward the inside of the shell 110, the unlocking clamping protrusion 136 can be clamped in the U-shaped space of the reinforcing member 120 such that the unlocking clamping protrusion 136 is limited. When the locking tongue 212 is clamped with the reinforcing member 120, an end portion of the locking tongue 212 abuts against end portions of the support arm 122. At this time, if the unlocking member 130 slides toward the outside of the shell 110, the force can be exerted on the locking tongue 212 through the unlocking clamping protrusion 136 such that the end portion of the locking tongue 212 deviates from the end portions of the support arm 122, thereby undoing the clamping to the reinforcing member 120.

As shown in FIG. 6, the unlocking clamping protrusion 136 includes an extending portion 1362 and a bending portion 1364 that are connected with each other. The extending portion 1362 is connected with the connecting arm 134, and there is a preset included angle between the extending portion 1362 and the connecting arm 134. The bending portion 1364 bends toward an inner side of the unlocking member 130.

Specifically, by setting the preset included angle between the extending portion 1362 and the connecting arm 134, the extending portion 1362 forms a guide slope. As the unlocking member 130 moves relative to the shell 110 toward the unlocking direction, the unlocking clamping protrusion 136 can make the locking tongue 212 gradually deviate away from the reinforcing member 120, so as to undo the clamping of the locking tongue 212 to the reinforcing member 120. In addition, by making the bending portion 1364 bend toward the inner side of the unlocking member 130, a smooth transition between the extending portion 1362 and the locking tongue 212 is ensured, thereby avoiding getting stuck. It can be understood that the unlocking clamping protrusion 136 and the connecting arm 134 can be integrally bent and formed, which helps in reducing the production cost.

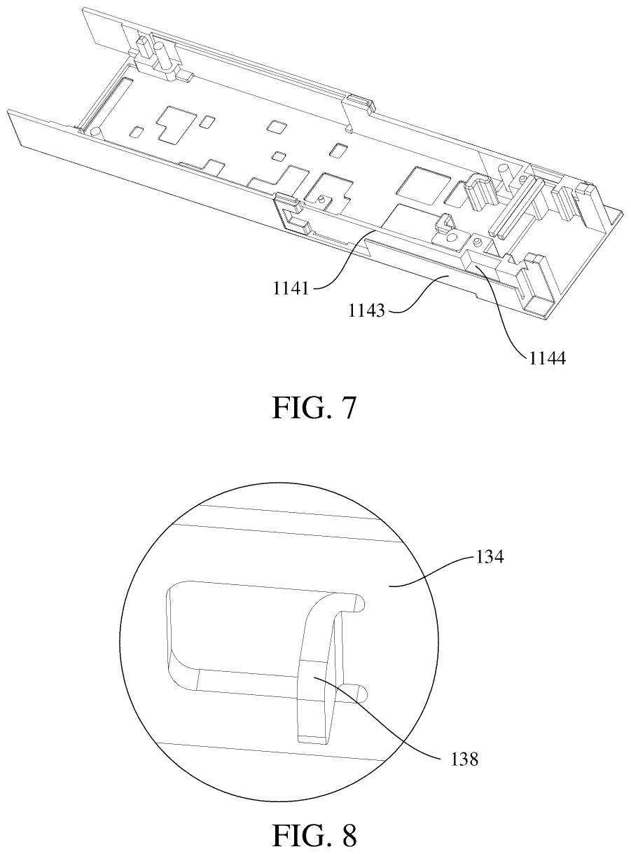

As shown in FIG. 5 and FIG. 7, the bottom case 114 includes first baffles 1141 and second baffles 1143 that are spaced apart, and a sliding groove is formed between the first baffle 1141 and the second baffle 1143 such that the connecting arm 134 slides along the sliding groove.

Specifically, through the sliding groove formed between the first baffle 1141 and the second baffle 1143, the connecting arm 134 can be limited between the first baffle 1141 and the second baffle 1143, which can ensure the connecting arm 134 to slide along a specific track. In addition, when the bottom case 114 and the top cover 116 are fastened, the top cover 116 can also limit the connecting arm 134, so as to ensure that the connecting arm 134 always slides in the sliding groove.

As shown in FIG. 5, FIG. 7 and FIG. 8, the connecting arm 134 is provided with a hook 138, the first baffle 1141 is formed with a clamping groove 1144, and the hook 138 is located in the clamping groove 1144.

Specifically, by making the hook 138 located in the clamping groove 1144, when the connecting arm 134 slides relative to the sliding groove, the length that the connecting arm can slide is the length of the clamping groove 1144, so that the sliding distance of the unlocking member 130 can be limited, thereby preventing the unlocking member 130 from sliding out of the shell 110. The hook 138 and the connecting arm 134 can be integrally bent and formed, which helps in reducing the production cost. In addition, the unlocking member 130 of this application is simple and effective in structure and does not need any complicated motion transmission form, which helps in lowering the overall production cost.

In an optional embodiment of this application, the reinforcing members 120 are made of stainless steel, tool steel or die steel. This can lower the production cost on the premise of ensuring the strength of the reinforcing members 120 and avoiding damage caused by scraping.

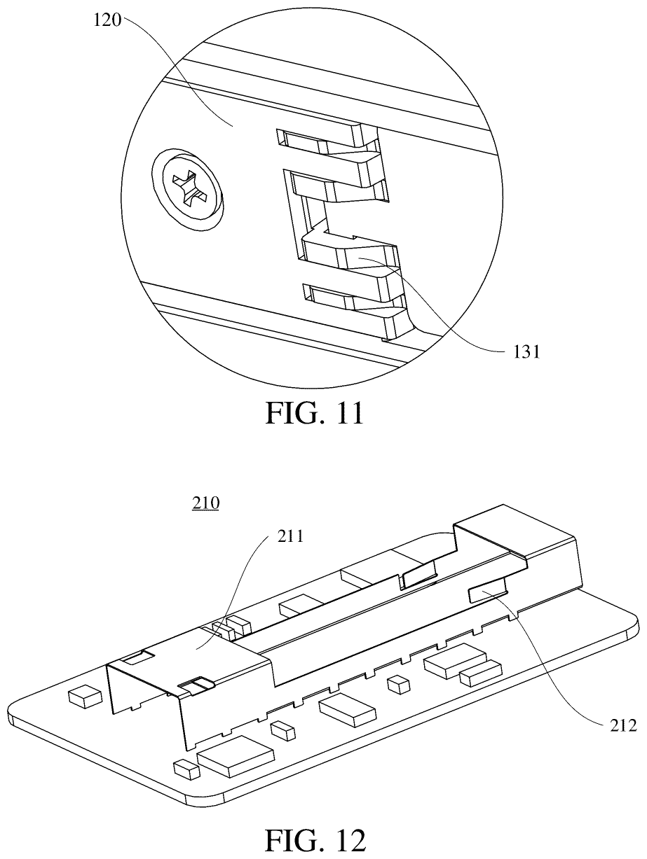

As shown in FIG. 10, FIG. 11 and FIG. 12, in another optional embodiment of this application, the unlocking member 130 is provided with abutting blocks 131, and the abutting blocks 131 are capable of abutting against the locking tongues 212 such that the unlocking member 130 undoes the clamping and limiting of the locking tongues 212 to the reinforcing members 120 through the abutting blocks 131.

Specifically, the abutting blocks 131 mainly function to change the clamped state between the locking tongues 212 and the reinforcing members 120 by abutting against the locking tongues 212 of the cage 210 when the optical module 100 needs to be taken out, so as to undo the clamping and limiting of the locking tongues 212 to the reinforcing members 120, so that the optical module 100 can be easily pulled out of the cage 210. The abutting block 131 abutting against the locking tongue 212 can prevent deformation failure itself from affecting the abutting against the locking tongue 212, so that the optical module 100 can be plugged in and pulled out more smoothly, and the reliability during unlocking can be improved.

As shown in FIG. 11 and FIG. 13, the unlocking member 130 includes a handle 132 and connecting arms 134 connected with the handle 132. A tail end of each of the connecting arms 134 is provided with a limiting portion 1342, and the limit portion 1342 is in a snap-fit with the abutting block 131.

Specifically, the handle 132 is the position where the user operates the unlocking member 130, so that the user can drive the unlocking member 130 to slide relative to the shell 110 by pulling the handle 132. The connecting arm 134 connects the handle 132 with the abutting block 131, and functions to transmit pulling force. The tail end of each of the connecting arms 134 is provided with the limiting portion 1342, and the limiting portion 1342 is configured to form a snap-fit with the abutting block 131. Through this snap-fit, the pulling force of the handle 132 can be transmitted to the abutting block 131, so that the abutting block 131 can abut against the locking tongue 212.

As shown in FIG. 13, the two opposite sides of the bottom case 114 are further provided with sliding slots 1142 for limiting the abutting blocks 131, and part of the reinforcing member 120 extends to the sliding slot 1142 to form a sliding fit with the abutting block 131.

Specifically, part of the reinforcing member 120 extends to the sliding slot 1142 to form a sliding fit with the abutting block 131, so that during the unlocking process, the reinforcing member 120 can better guide the motion of the abutting block 131, and the abutting block 131 can more effectively undo the clamped state between the reinforcing member 120 and the locking tongue 212. This close fit improves the overall performance of the unlocking structure of the optical module 100 and reduces possible failure during the unlocking process. In addition, the two opposite sides of the bottom case 114 are provided with the sliding slots 1142. The sliding slot 1142 functions to limit the abutting block 131, so that the abutting block 131 can only slide within the range limited by the sliding slot 1142. Thereby, when the handle 132 is pulled for unlocking, the whole optical module 100 can be driven to leave the cage 210 after the unlocking action is completed, thereby preventing the unlocking member 130 from sliding out of the shell 110.

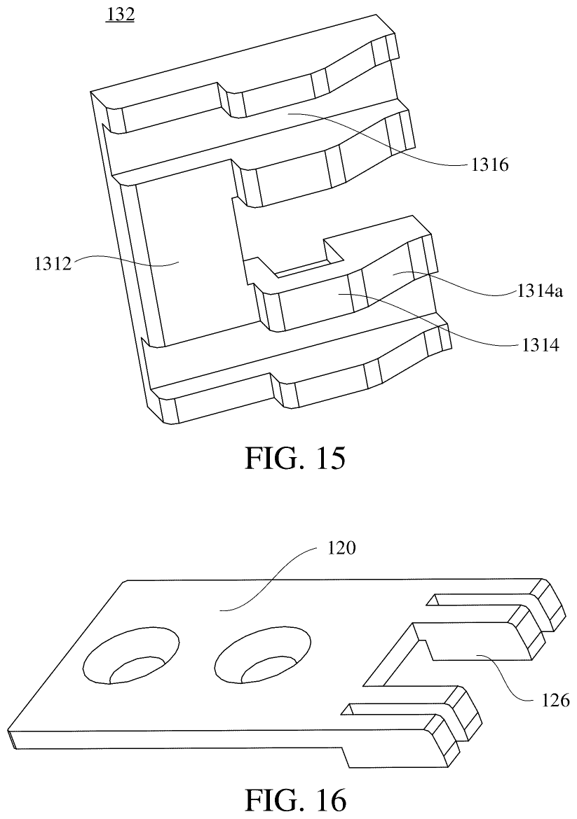

As shown in FIG. 14, FIG. 15 and FIG. 16, the abutting block 131 includes a base 1312 connected with the limiting portion 1342 and a plurality of ribs 1314 formed at one side of the base 1312. The ribs 1314 are each formed with a guide slope 1314a to be fitted with an end portion of the locking tongue 212. Guide grooves 1316 are formed between the adjacent ribs 1314. The reinforcing member 120 is formed with guide bumps 126 corresponding to the ribs 1314. The guide slots 1316 are slidable along the guide bumps 126.

Specifically, with the design of the guide slopes 1314a, when the abutting block 131 abuts against the locking tongue 212, the locking tongue 212 can be guided to be deformed or move more effectively, so that the clamping of the locking tongue 212 to the reinforcing member 120 can be undone more easily, thereby reducing the force required for unlocking and improving the convenience of the unlocking operation. Moreover, the existence of the guide slopes 1314a can also reduce the friction between the locking tongue 212 and the abutting block 131, thereby reducing the abrasion caused by friction and prolonging the service life of the optical module 100 and the cage 210. In addition, through the fit between the guide grooves 1316 and the guide bumps 126, the abutting block 131 can move along a fixed trajectory during the sliding process, which further improves the stability and accuracy of the movement of the abutting block 131. This fit can effectively prevent the abutting block 131 from deviating and getting stuck during the sliding process, thereby ensuring the smoothness of the unlocking operation and improving the strength and reliability of connection between the reinforcing member 120 and the abutting block 131.

In an optional embodiment of this application, the limiting portion 1342 is T-shaped or L-shaped, and the base 1312 is provided with an insertion groove 1312a and a snap-fit groove 1312b located at at least one side of the insertion groove 1312a such that the limiting portion 1342 snaps into the snap-fit groove 1312b.

Specifically, through the fit between the T-shaped or L-shaped limiting portion 1342, and the insertion groove 1312a and the snap-fit groove 1312b in the base 1312, the limiting portion 1342 and the base 1312 can be assembled easily and quickly. During production, the worker may easily make the limiting portion 1342 snap into the snap-fit groove 1312b without using any complicated tool or process, thereby improving the production efficiency and lowering the production cost. In actual application, the snap-fit grooves 1312b face an inner side of the shell 110. When the optical module 100 is in use, the base 1312 is stopped by the reinforcing members 120 and side walls of the shell 110, so that the limiting portions 1342 will not be separated from the base 1312, thereby ensuring the normal connection and operation of the components of the unlocking member 130, and ensuring the stability and reliability of the unlocking structure of the optical module 100. If the limiting portion 1342 is T-shaped, two sides of the insertion groove 1312a need to be provided with the snap-fit grooves 1312b. If the limiting portion 1342 is L-shaped, only one side of the insertion groove 1312a needs to be provided with the snap-fit groove 1312b.

As shown in FIG. 13, the connecting arm 134 is provided with a hook 138. Side walls of the bottom case 114 are each formed with a clamping groove 1144. The hook 138 extends into the clamping groove 1144. An elastic member 1146 is arranged in the clamping groove 1144. Two ends of the elastic member 1146 respectively abut against the hook 138 and one side wall of the clamping groove 1144 such that the connecting arm 134 is subjected to an elastic force of sliding into the shell 110.

Specifically, with the elastic member 1146 arranged, the connecting arm 134 can automatically return to its initial state after the unlocking operation is completed, which makes the operation process more convenient and faster, and improves the convenience of use of the optical module 100. After the user plugs in and pulls out the optical module 100, no additional operation is required to make the unlocking member 130 return to its initial state, thereby reducing the operation steps and improving the working efficiency. In addition, through the fit of the hook 138, the clamping groove 1144 and the elastic member 1146, the connecting arm 134 can move more stably during the sliding process. The elastic member 1146 can buffer the impact force exerted on the connecting arm 134 during the sliding process to some extent, and also ensures the accuracy and reliability of the connecting arm 134 during the unlocking and returning process, thereby improving the overall stability of the unlocking structure of the optical module 100.

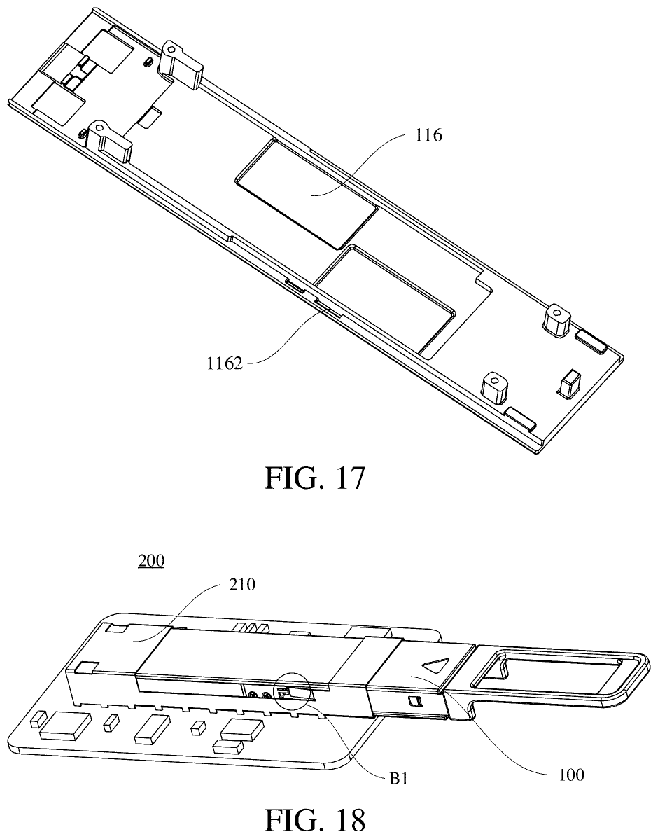

As shown in FIG. 13 and FIG. 17, a side of each of the connecting arms 134 in a width direction is formed with a limiting protrusion 1344. The top cover 116 is formed with limiting grooves 1162 corresponding to the limiting protrusions 1344. The limiting protrusion 1344 is slidably clamped in the limiting groove 1162.

Specifically, a width of the limiting protrusion 1344 is less than a width of the limiting groove 1162, and while the handle 132 is pulled, the limiting protrusion 1344 can slide a certain distance along the limiting groove 1162. Besides, during the returning process, the limiting protrusion 1344 can only slide within the range limited by the limiting groove 1162, so that during the unlocking process by pulling the handle 132, the unlocking member 130 can be prevented from sliding out of the shell 110. Moreover, in combination with the fit between the abutting block 131 and the sliding slot 1142, a concentrated force exerted on the optical module 100 can be avoided during the unlocking process, which helps in improving the stability during use.

In an optional embodiment of this application, the abutting blocks 131 are made of stainless steel, tool steel or die steel.

Specifically, the abutting blocks 131 made of stainless steel, tool steel or die steel have higher strength and hardness. The optical module 100 can better bear the interaction force with the locking tongues 212 during the plugging and unlocking process, thereby reducing deformation and damage caused by scraping and squeezing. Moreover, these materials have better wear resistance, which can effectively reduce the abrasion caused by the components such as the locking tongues 212 and prolong the service life of the optical module 100 and the cage 210.

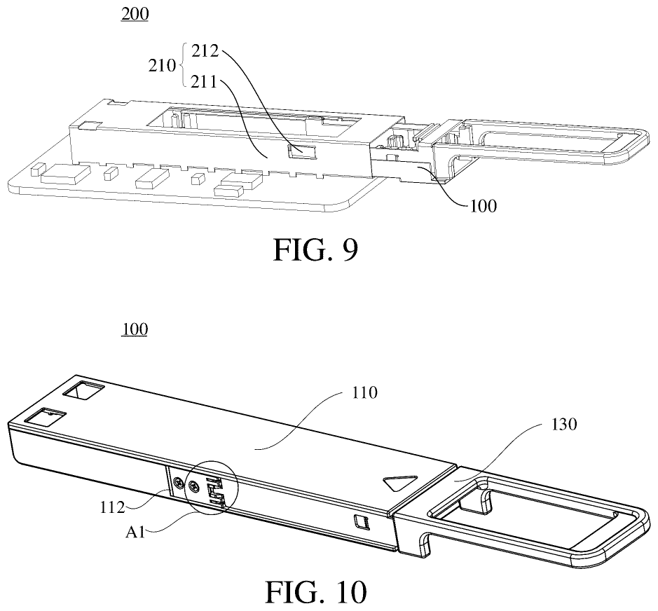

As shown in FIG. 9, FIG. 18 and FIG. 20, an embodiment of this application further discloses an optical transceiver connection assembly 200, including a cage 210 and the optical module 100 in the foregoing embodiment. The optical module 100 is pluggably connected with the cage 210. The optical transceiver connection assembly 200 includes the same structure and beneficial effects as the optical module 100 in the foregoing embodiment. The structure and beneficial effects of the optical module 100 have been described in detail in the foregoing embodiment and will not be repeated here.

Referring to FIG. 9 and FIG. 18 to FIG. 21, the cage 210 includes an enclosure 211 and locking tongues 212 arranged at two opposite sides of the enclosure 211, and the locking tongues 212 bend toward an inner side of the enclosure 211 so as to be clamped with reinforcing members 120 of the optical module 100.

Specifically, the enclosure 211 and the locking tongues 212 may be integrally bent and formed. In the initial state, the locking tongues 212 bend toward the inner side of the enclosure 211. When the shell 110 of the optical module 100 slides into the enclosure 211, the locking tongues 212 are deformed by force to ensure that the shell 110 can smoothly slide into the enclosure. When the shell 110 slides to such a depth that the reinforcing members 120 correspond to the locking tongues 212, the locking tongues 212 are restored to their initial shape and clamped with the reinforcing members 120. When the optical module 100 needs to be removed, the locking tongues 212 are deformed again through the unlocking members 130 to undo the clamping to the reinforcing members 120, so that the optical module 100 can be taken out smoothly.

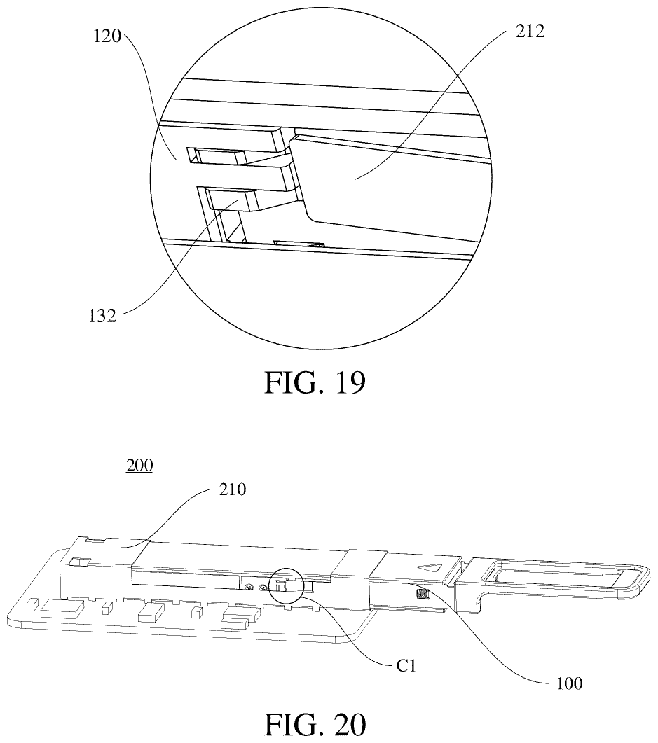

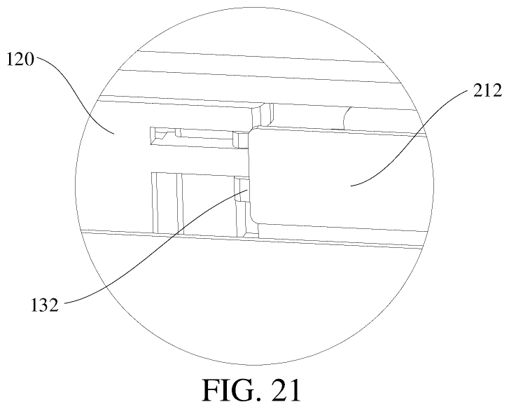

It should be noted that when the abutting blocks 131 are connected to the unlocking member 130, referring to FIG. 18 to FIG. 21 in which FIG. 18 is a schematic view of the optical transceiver connection assembly 200 in a locked state, an end portion of the locking tongue 212 abuts against the reinforcing member 120 (referring to FIG. 19) so as to limit the optical module 100. Referring to FIG. 20, when the optical module needs to be unlocked, the handle 132 is pulled to make the abutting blocks 131 abut against the locking tongues 212 and drive the locking tongues 212 to be deformed (referring to FIG. 21), so as to undo the limiting of the locking tongues 212 to the reinforcing members 120, so that the optical module 100 can be easily taken out of the cage 210.

It should be noted that the above embodiments are only used to illustrate the technical solutions of this application and are not intended to limit this application. Those skilled in the art can modify the technical solutions described in the above embodiments, or make equivalent substitutions to some technical features. All these modifications and substitutions shall fall into the protection scope of the appended claims of this application.

What is claimed is:

1. An optical module, comprising a shell and mounting portions arranged at two opposite sides of the shell, the mounting portions being each provided with a reinforcing member, an unlocking member being further slidably connected in the shell, the shell being pluggable into a cage and clamped with locking tongues of the cage through the reinforcing members, and the unlocking member being capable of undoing the clamping of the locking tongues to the reinforcing members.

2. The optical module according to claim 1, wherein the shell comprises a bottom case and a top cover that are fastened with each other, the mounting portions are located at two opposite sides of the bottom case, and the unlocking member is slidably connected with the bottom case.

3. The optical module according to claim 2, wherein the reinforcing member has a U-shaped structure, support arms of the reinforcing member are respectively provided with a positioning protrusion, and the bottom case and the top cover are respectively provided with positioning grooves such that the positioning protrusions snap into the positioning grooves.

4. The optical module according to claim 3, wherein the unlocking member comprises a handle and connecting arms connected with the handle, the connecting arms are each provided with an unlocking clamping protrusion, and the unlocking clamping protrusion is configured to abut against the locking tongue.

5. The optical module according to claim 4, wherein the unlocking clamping protrusion comprises an extending portion and a bending portion that are connected with each other, the extending portion is connected with the connecting arm, there is a preset included angle between the extending portion and the connecting arm, and the bending portion bends toward an inner side of the unlocking member.

6. The optical module according to claim 4, wherein the bottom case comprises first baffles and second baffles that are spaced apart, and a sliding groove is formed between the first baffle and the second baffle such that the connecting arm slides along the sliding groove.

7. The optical module according to claim 6, wherein the connecting arm is provided with a hook, the first baffle is formed with a clamping groove, and the hook is located in the clamping groove.

8. The optical module according to claim 1, wherein the reinforcing members are made of stainless steel, tool steel or die steel.

9. The optical module according to claim 2, wherein the unlocking member is provided with abutting blocks, and the abutting blocks are capable of abutting against the locking tongues such that the unlocking member undoes the clamping and limiting of the locking tongues to the reinforcing members through the abutting blocks.

10. The optical module according to claim 9, wherein the unlocking member comprises a handle and connecting arms connected with the handle, a tail end of each of the connecting arms is provided with a limiting portion, and the limit portion is in a snap-fit with the abutting block.

11. The optical module according to claim 10, wherein the two opposite sides of the bottom case are further provided with sliding slots for limiting the abutting blocks, and part of the reinforcing member extends to the sliding slot to form a sliding fit with the abutting block.

12. The optical module according to claim 11, wherein the abutting block comprises a base connected with the limiting portion and a plurality of ribs formed at one side of the base, the ribs are each formed with a guide slope to be fitted with an end portion of the locking tongue, guide grooves are formed between the adjacent ribs, the reinforcing member is formed with guide bumps corresponding to the ribs, and the guide slots are slidable along the guide bumps.

13. The optical module according to claim 12, wherein the limiting portion is T-shaped or L-shaped, and the base is provided with an insertion groove and a snap-fit groove located at at least one side of the insertion groove such that the limiting portion snaps into the snap-fit groove.

14. The optical module according to claim 13, wherein the connecting arm is provided with a hook, side walls of the bottom case are each formed with a clamping groove, the hook extends into the clamping groove, an elastic member is arranged in the clamping groove, and two ends of the elastic member respectively abut against the hook and one side wall of the clamping groove such that the connecting arm is subjected to an elastic force of sliding into the shell.

15. The optical module according to claim 14, wherein a side of each of the connecting arms in a width direction is formed with a limiting protrusion, the top cover is formed with limiting grooves corresponding to the limiting protrusions, and the limiting protrusion is slidably clamped in the limiting groove.

16. The optical module according to claim 9, wherein the abutting blocks are made of stainless steel, tool steel or die steel.

17. An optical transceiver connection assembly, comprising a cage and the optical module according to claim 1, the optical module being pluggably connected with the cage.

18. The optical transceiver connection assembly according to claim 17, wherein the cage comprises an enclosure and locking tongues arranged at two opposite sides of the enclosure, and the locking tongues bend toward an inner side of the enclosure so as to be clamped with reinforcing members of the optical module.
